(19) United States
(12) Patent Application Publication
(10) Pub. No.: US 2025/0268031 A1
(43) Pub. Date: Aug. 21, 2025

(54) DISPLAY DEVICE

(71) Applicant: LG Display Co., Ltd., Seoul (KR)

(72) Inventor: WonJu KWON, Bucheon-si (KR)

(73) Assignee: LG Display Co., Ltd., Seoul (KR)

(21) Appl. No.: 18/678,398

(22) Filed: May 30, 2024

(30) Foreign Application Priority Data
Feb. 21, 2024 (KR) 10-2024-0025087

(51) Int. Cl. H10K 59/131; H10K 59/80; H10K 77/10; H10K 102/00

(52) U.S. Cl. CPC H10K 59/131; H10K 59/8723; H10K 77/111; H10K 2102/311

(57) ABSTRACT

A display device according to an example of the present disclosure includes a substrate having an active area and a first non-active area which encloses the active area, at least one metal layer disposed on at least one side portion of the substrate and having one surface exposed to an outside, and a support member. Here, the support member is disposed on a bottom surface of the substrate and includes at least one groove on at least one side surface of the support member. The exposed metal layer and the groove disposed on the side surface of the support member are disposed so as to correspond to each other.

### CROSS-REFERENCE TO RELATED APPLICATIONS

This application claims priority to Korean Patent Application No. 10-2024-0025087 filed on Feb. 21, 2024, in the Korean Intellectual Property Office, the entire disclosure of which is hereby expressly incorporated by reference into the present application.

### BACKGROUND

### Field

The present disclosure relates to a display device and more particularly, to a display device in which a support member is disposed in a lower portion of the display device.

### Discussion of the Related Art

In a full-scale information era, a field of a display device which visually expresses electrical information signals has been rapidly developed and studies are continuing to improve the performances of various display devices by providing thin-thickness, light weight, and low power consumption advantages.

Among the various display devices, a light emitting display device is a self-emitting display device where a separate light source is not necessary, which is different from a liquid crystal display device. Therefore, the light emitting display device can be manufactured to have light weight and small thickness.

Further, since the light emitting display device is driven at a low voltage, it is advantageous not only in terms of power consumption, but also in terms of color implementation, a response speed, a viewing angle, a contrast ratio (CR). Therefore, the light emitting display device is expected to be utilized in various fields with wide applications.

### SUMMARY OF THE DISCLOSURE

An object to be achieved by the present disclosure is to provide a display device with a reduced bezel area by making a display panel and a support member disposed below the display panel correspond to each other at the same area ratio.

Another object to be achieved by the present disclosure is to provide a display device which includes a metal layer exposed on a side surface of a display panel and includes at least one groove on a side surface of the support member to align the display panel and the support member through the side surface, rather than a top surface or a bottom surface of the display panel.

Objects of the present disclosure are not limited to the above-mentioned objects, and other objects, which are not mentioned above, can be clearly understood by those skilled in the art from the following descriptions.

According to an aspect of the present disclosure, a display device comprises a substrate including an active area and a first non-active area which encloses the active area, at least one metal layer which is disposed on at least one side portion of the substrate and includes one surface exposed to an outside and a support member which is disposed on a bottom surface of the substrate and includes at least one groove on at least one side surface of the support member, wherein the at least one exposed metal layer and the at least one groove disposed on the side surface of the support member are disposed so as to correspond to each other.

Other detailed matters of the embodiments of the present disclosure are included in the detailed description and the drawings.

According to an aspect of the present disclosure, a metal layer exposed on a side surface of the display panel is included and a groove is included on a side surface of the support member disposed below the display panel to align the display panel and the support member through side surface observation.

According to an aspect of the present disclosure, the display panel and the support member are aligned through side surface observation to dispose the support member so as to correspond to the entire area of the display panel.

According to an aspect of the present disclosure, the support member is disposed so as to correspond to the entire area of the display panel to minimize the bezel area.

The effects according to various aspects of the present disclosure are not limited to the contents exemplified above, and more various effects are included in the present disclosure.

The effects of the present disclosure are not limited to the aforementioned effects, and other effects, which are not mentioned above, will be apparently understood to a person having ordinary skill in the art from the following description.

The objects to be achieved by the present disclosure, the means for achieving the objects, and the effects of the present disclosure described above do not specify essential features of the claims, and, thus, the scope of the claims is not limited to the disclosure of the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a plan view of a display device according to an embodiment of the present disclosure before bending a display panel;

FIG. 2 is a rear view of a display device according to an embodiment of the present disclosure;

FIG. 3 is a cross-sectional view taken along the line III-III′ of FIG. 2 according to an example of the present disclosure;

FIG. 4 is a side view of an area A of FIG. 2 according to an example of the present disclosure; and

FIG. 5 is an enlarged cross-sectional view of an area B of FIG. 3 according to an example of the present disclosure.

### DETAILED DESCRIPTION OF THE EMBODIMENTS

Advantages and characteristics of the present disclosure and a method of achieving the advantages and characteristics will be clear by referring to exemplary embodiments described below in detail together with the accompanying drawings. However, the present disclosure is not limited to the embodiments disclosed herein but will be implemented in various forms. The embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the embodiments of the present disclosure are merely examples, and the present disclosure is not limited thereto. Like reference numerals generally denote like elements throughout the disclosure. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When an element or layer is disposed “on” another element or layer, another layer or another element can be interposed directly on the other element or therebetween.

Although the terms “first”, “second”, and the like are used for describing various components, these components are not confined by these terms. These terms are merely used for distinguishing one component from the other components and may not define order or sequence. Therefore, a first component to be mentioned below can be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other. Further, all the components of each display device according to embodiments of the present disclosure are operatively coupled and configured.

Hereinafter, embodiments of the present disclosure will be described in detail with reference to accompanying drawings.

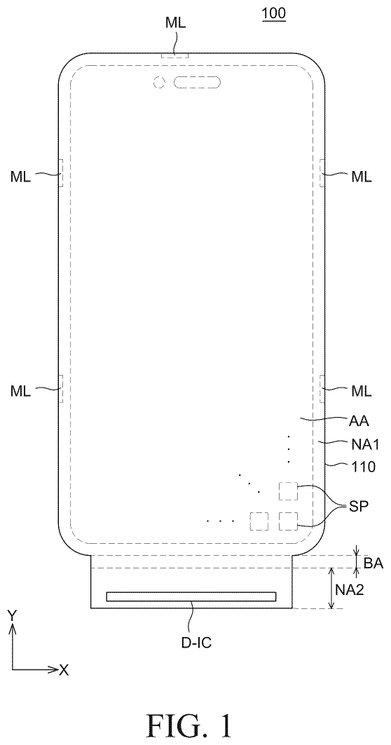

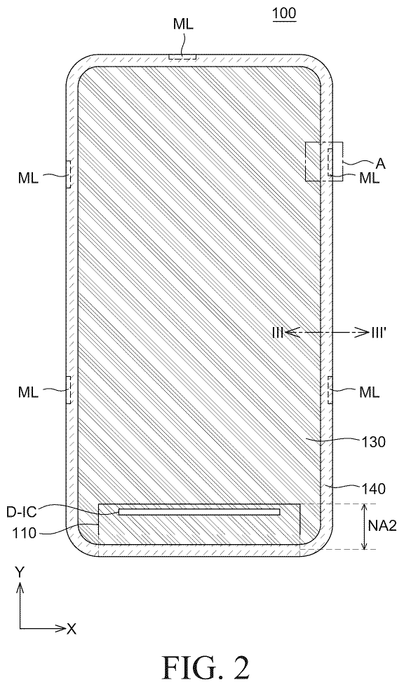

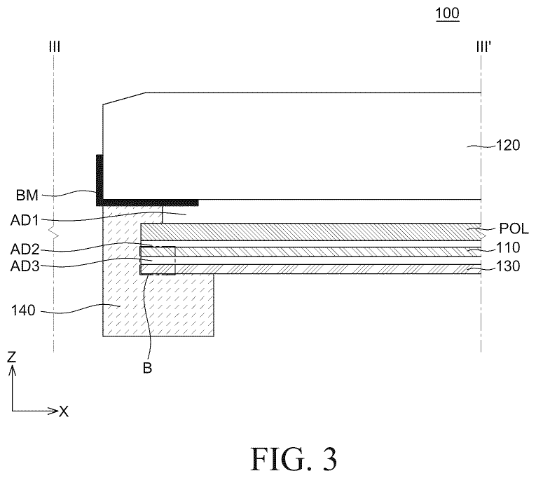

FIG. 1 is a plan view of a display device according to an embodiment of the present disclosure before bending a display panel. FIG. 2 is a rear view of a display device according to an embodiment of the present disclosure. FIG. 3 is a cross-sectional view taken along the line III-III′ of FIG. 2 according to an example of the present disclosure.

In FIGS. 1 to 3, for the convenience of description, among components of a display device 100, here a display panel 110, a cover window 120, a support member 130, and a molding member 140 are illustrated.

First, referring to FIGS. 1 to 3, the display device 100 according to the embodiment of the present disclosure can include the display panel 110, the cover window 120, the support member 130, and the molding member 140.

The display panel 110 is a panel for displaying images to a user. In the display panel 110, a display element LED which displays images, a driving element which drives the display element LED, and wiring lines which transmit various signals to the display element LED and the driving element can be disposed.

The display element LED can be defined in different manners depending on the type of the display panel 110. For example, when the display panel 110 is an organic light emitting display panel, the display element can be an organic light emitting diode which includes an anode, an organic emission layer, and a cathode. For example, when the display panel 110 is a liquid crystal display panel, the display element can be a liquid crystal display element. Hereinafter, even though the display panel 110 is assumed as an organic light emitting display panel, the display panel 110 is not limited to the organic light emitting display panel.

The display panel 110 includes an active area AA and a non-active area.

The active area AA is an area where images are displayed in the display panel 110. In the active area AA, a plurality of sub pixels SP which configures a plurality of pixels and a driving circuit for driving the plurality of sub pixels SP can be disposed.

The plurality of sub pixels SP is minimum units which configure the active area AA and a display element can be disposed in each of the plurality of sub pixels SP. For example, an organic light emitting diode which includes an anode, an organic emission layer, and a cathode can be disposed in each of the plurality of sub pixels SP, but it is not limited thereto. Further, the driving circuit for driving the plurality of sub pixels SP can include a driving element, a wiring line, and the like. For example, the driving circuit can be configured by a thin film transistor, a storage capacitor, a gate line, a data line, and the like, but is not limited thereto.

The non-active area (or non-display area) is an area in which no image is displayed. The non-active area can refer to an outer peripheral portion of the display panel 110 which encloses the active area AA. A part of the non-active area can overlap the black matrix BM. In the non-active area, various wiring lines and circuits for driving the display element LED of the active area AA can be disposed. For example, in the non-active area, a link line which transmits signals to the plurality of sub pixels SP and driving circuits of the active area AA or a driving IC (D-IC) such as a gate driver IC or a data driver IC can be disposed, but it is not limited thereto.

The non-active area can include a first non-active area NA1, a bending area BA, and a second non-active area NA2, but can include other areas or different combinations of similar areas.

The first non-active NA1 is an area which encloses the active area AA and extends from the active area AA. The bending area BA can extend from one side of the first non-active area NA1 and can be bent. The second non-active area NA2 is an area which extends from the bending area BA to be disposed below the active area AA.

In the meantime, referring to FIGS. 1 and 2, the first non-active area NA1 and the second non-active area NA2 can be disposed on the same plane as the active area AA or disposed to be parallel to the active area AA and maintain a flat state. For example, the first non-active area NA1 can be disposed to be flat on the same plane as the active area AA and the second non-active area NA2 can be disposed below the active area AA to be flat and parallel to the active area AA. Therefore, the active area AA, the first non-active area NA1, and the second non-active area NA2 can be referred to as non-bending areas, but are not limited thereto.

Referring to FIGS. 1 and 2, the driving IC D-IC is disposed in the second non-display area NA2. The driving IC D-IC can supply a data signal to the plurality of sub pixels SP. For example, the driving IC D-IC can sample and latch the data signal supplied from the timing controller in response to a data timing control signal supplied from the timing controller to convert the data signal into a gamma reference voltage and output the converted gamma reference voltage. The driving IC D-IC can output a data signal through the plurality of data lines. For example, in the second non-active area NA2 in which the driving IC D-IC is disposed, a pad unit is disposed and a printed circuit board which is electrically connected to the pad unit is further disposed to supply a signal to the driving IC D-IC, but is not limited thereto.

In the meantime, the driving IC D-IC is disposed on one side of the display panel 110 in a chip on panel (COP) manner to be connected to the display panel 110 or is disposed in a separate flexible film to be connected to the display panel 110 in a chip on film (COF) manner. In the display device 100 according to the embodiment of the present disclosure, it is assumed that the driving IC D-IC is disposed in the COP manner, but it is not limited thereto.

Referring to FIGS. 1 and 2, as the display panel 110 is bent, the driving IC D-IC disposed in the second non-active area NA2 is disposed below the active area AA. For example, the driving IC D-IC and the printed circuit board connected to the pad unit of the display panel 110 can move to the rear surface of the display panel 110 and can overlap the active area AA. Therefore, as seen from the top of the display panel 110, circuit elements, such as the driving IC D-IC and the printed circuit board may not be visible. Accordingly, a size of the non-active area which is visible from the top of the display panel 110 is reduced to implement a narrow bezel.

Referring to FIG. 3, a cover window 120 can be disposed on a front surface of the display panel 110. The cover window 120 can be a component which is exposed to the outer periphery of the display device 100 and protects the display device 100 from external impact or scratches. Further, the cover window 120 can protect the display device 100 from moisture, etc. permeating from the outside. The cover window 120 can be formed of a glass or a plastic material having a flexibility, but is not limited thereto.

A black matrix BM can be disposed below the cover window 120. The black matrix BM can be disposed along the periphery of the cover window 120 at the outer periphery of the cover window 120. At this time, the area in which the black matrix BM is disposed can correspond to the first non-active area NA1. The black matrix BM can be formed of a material having a low permeability. Therefore, the black matrix BM can suppress various components disposed below the first non-active area NA1 from being visible to the outside. Further, the black matrix BM is formed of a material having a conductivity to discharge static electricity from the cover window 120.

The black matrix BM can be configured by chrome (Cr), graphite, or resin including conductive particles. Here, the resin can be formed of one or more materials of acrylic resin, epoxy resin, phenolic resin, polyamides resin, polyimides resin, unsaturated polyesters resin, polyphenylene resin, polyphenylenesulfides resin, and benzocyclobutene, but is not limited thereto. Further, the conductive particle can also be formed of any one of molybdenum (Mo), chrome (Cr), titanium (Ti), nickel (Ni), neodymium (Nd), copper (Cu), and an alloy of silver (Ag) and magnesium (Mg), but is not limited thereto.

Further, a polarizer POL can be disposed between the display panel 110 and the cover window 120. The polarizer POL can be disposed on the front surface of the display panel 110. The polarizer POL selectively transmits light to reduce the reflection of external light which is incident onto the display panel 110. Specifically, the display panel 110 includes various metal materials applied to the semiconductor element, the wiring line, the organic light emitting diode, and the like. Therefore, the external light incident onto the display panel 110 can be reflected from the metal material so that the visibility of the display device 100 can be reduced due to the reflection of the external light. In contrast, when the polarizer POL is disposed, the polarizer POL suppresses the reflection of the external light so that the outdoor visibility of the display device 100 can be increased. However, the polarizer POL can be omitted depending on an implementation example of the display device 100, but it is not limited thereto.

A first adhesive layer AD1 can be disposed between the polarizer POL and the cover window 120 and a second adhesive layer AD2 can be disposed between the polarizer POL and the display panel 110. The first adhesive layer AD1 can bond the cover window 120 and the polarizer POL and the second adhesive layer AD2 can bond the polarizer POL and the display panel 110. As a result, the first adhesive layer AD1 and the second adhesive layer AD2 can bond the display panel 110 and the cover window 120. The first adhesive layer AD1 and the second adhesive layer AD2 can be formed as transparent adhesive layers so that an image of the display panel 110 is visible. For example, the first adhesive layer AD1 and the second adhesive layer AD2 can be formed of optical clear adhesives, but are not limited thereto.

A support member 130 is disposed below the display panel 110. The support member 130 can protect the components of the display device 100 from external impacts. Further, the support member 130 serves as a ground to suppress the static electricity entering the display device 100 or easily discharge residual charges accumulated in the display device 100 to the outside. Further, the support member 130 can easily discharge heat generated in the display device 100 to the outside. The support member 130 can be formed of a metal material having excellent thermal conductivity, electrical conductivity, and mechanical rigidity. For example, the support member 130 can be configured by copper (Cu) or stainless steel (SUS), but is not limited thereto.

The display panel 110 and the support member 130 can be bonded by a third adhesive layer AD3. The third adhesive layer AD3 can bond the display panel 110 and the support member 130. The third adhesive layer AD3 can be formed of a pressure sensitive adhesive (PSA), but is not limited thereto.

A back plate can be further included between the display panel 110 and the support member 130. The back plate can be disposed to support the display panel 110. For example, when the substrate SUB of the display panel 110 is formed of a plastic material such as polyimide, due to the flexible property, a separate component for supporting the substrate SUB can be necessary. Therefore, a support substrate which is formed of glass is disposed below the substrate to perform a manufacturing process of the display device 100 and the support substrate can be separated to be released after completing the manufacturing process. However, a component for supporting the substrate is necessary even after releasing the support substrate, so that a back plate for supporting the substrate can be disposed below the display panel 110.

The back plate can include a plastic material. For example, the back plate can be formed of a plastic thin film formed of polyimide (PI), polyethylene naphthalate (PEN), polyethylene terephthalate (PET), or a combination of the polymers.

The bonding between the back plate and the display panel 110 and the back plate and the support member 130 can be performed by means of an additional adhesive layer. At this time, the additional adhesive layer can be formed of a pressure sensitive adhesive (PSA), but is not limited thereto.

The molding member 140 seals the cover window 120, the display panel 110, and the support member 130. Specifically, the molding member 140 can be disposed so as to enclose parts of a lower portion of the cover window 120, a side surface of the display panel 110, and a side surface of the support member 130. The molding member 140 can suppress the permeation of the moisture or oxygen into the display device 100. Further, the molding member 140 can protect components of the display device 100 and relieve impacts applied to the display device 100.

For example, the molding member 140 can be formed by a process of removing a mold, after filling and curing the mold which is disposed to enclose a side surface of the cover window 120 and expose a side surface of the display panel 110 and a part of a side surface of the support member 130 with a material for forming the molding member 140. However, the method of forming the molding member 140 is not limited thereto.

The molding member 140 can be formed of one or more materials of acrylic resin, epoxy resin, phenolic resin, polyamides resin, polyimides resin, unsaturated polyesters resin, polyphenylene resin, polyphenylenesulfides resin, and benzocyclobutene, but is not limited thereto.

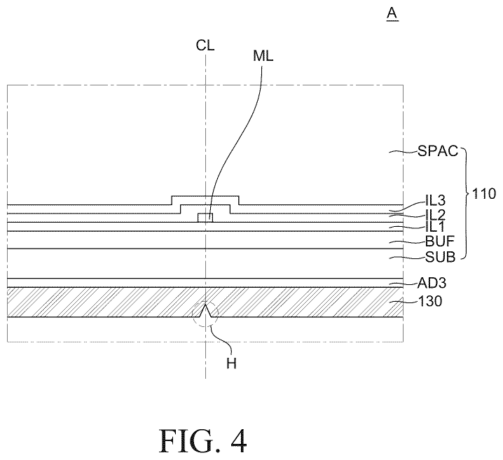

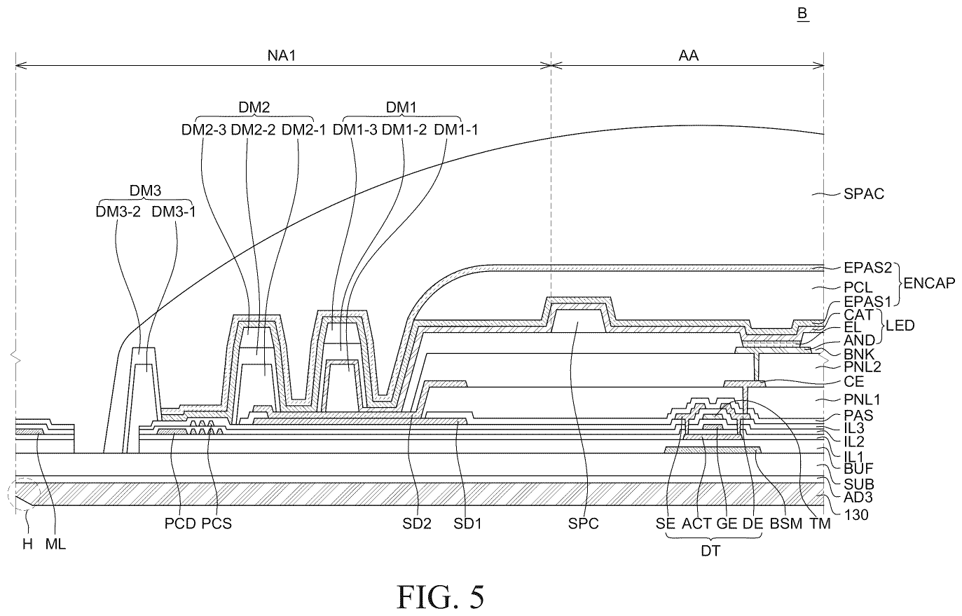

Hereinafter, a display panel 110 and a support member 140 of a display device 100 according to an embodiment of the present disclosure will be described in more detail with reference to FIGS. 4 and 5.

Particularly, FIG. 4 is a side view of an area A of FIG. 2. FIG. 5 is an enlarged cross-sectional view of an area B of FIG. 3. For the convenience of description, in FIG. 4, a display panel 110, a third adhesive layer AD3, and a support member 130, among various configurations of the display device 100, are illustrated. The display device 100 includes other components.

Referring to FIGS. 4 and 5, the display panel 110 can include a substrate SUB, a light shielding layer BSM, a buffer layer BUF, an insulating layer IL1, IL2, IL3, a planarization layer PNL1,PNL2, a driving transistor DT, a display element LED, a conductive layer TM, SD1, SD2, an encapsulation unit ENCAP, a dam DM, a crack sensing pattern PCD, a crack suppression pattern PCS, and the like.

The substrate SUB can support various components of the display device 100.

The substrate SUB can be formed of a plastic material having flexibility. When the substrate SUB is formed of a plastic material, for example, the substrate can be formed of polyimide (PI), but is not limited thereto.

In the active area AA of the substrate SUB, the light shielding layer BSM can be disposed on the substrate SUB. The light shielding layer BSM blocks light which is incident to active layers ACT of the plurality of transistors to minimize a leakage current. For example, the light shielding layer BSM is disposed below the active layer ACT of the driving transistor DT to block light incident onto the active layer ACT. If light is irradiated onto the active layer ACT, a leakage current can be generated, which can deteriorate the reliability of the transistor. Accordingly, the light shielding layer BSM which blocks the light is disposed on the substrate SUB to improve the reliability of the driving transistor DT. The light shielding layer BSM can be configured by an opaque conductive material such as copper (Cu), aluminum (Al), molybdenum (Mo), nickel (Ni), titanium (Ti), chrome (Cr), or an alloy thereof, but is not limited thereto.

The buffer layer BUF can be disposed on the light shielding layer BSM. The buffer layer BUF can reduce permeation of moisture or impurities through the substrate SUB. In each of the active area AA and the first non-active area NA1 of the substrate SUB, a plurality of buffer layers BUF which is spaced apart from each other can be disposed. First, the buffer layer BUF disposed in the active area AA can extend to a part of the first non-active area NA1. At this time, the buffer layer BUF extending to the part of the first non-active area NA1 can be cut off by a third dam DM3 disposed in the first non-active area NA1. Therefore, in a part of the first non-active area NA1 of the substrate SUB, the plurality of buffer layers BUF can be spaced apart from each other.

As such, in a part of the first non-active area NA1 of the substrate SUB, the buffer layer BUF may not be disposed. Some of the plurality of buffer layers BUF can be disposed to be in contact with an outermost periphery of the display panel 110 in the first non-active area NA1. Therefore, some side surfaces of the plurality of buffer layers BUF can be exposed to the outside of the display panel 110 through a side surface of the display panel 110.

For example, the buffer layer BUF can be configured by a single layer or a double layer of silicon oxide (SiOx) or silicon nitride (SiNx), but is not limited thereto. However, the buffer layer BUF can be omitted depending on a type of substrate SUB or a type of transistor, but is not limited thereto.

In FIGS. 4 and 5, an additional buffer layer can be disposed between the substrate SUB and the light shielding layer BSM. The additional buffer layer can be configured by, for example, a single layer or a double layer of silicon oxide (SiOx) or silicon nitride (SiNx) to reduce permeation of moisture or impurities through the substrate SUB, like the buffer layer BUF.

In the active area AA of the substrate SUB, a plurality of transistors can be disposed on the buffer layer BUF. For example, a driving transistor DT for driving the display element LED can be disposed on the buffer layer BUF. The driving transistor DT can include an active layer ACT, a gate electrode GE, a source electrode SE, and a drain electrode DE.

In the active area AA of the substrate SUB, the active layer ACT of the driving transistor DT can be disposed on the buffer layer BUF. The active layer ACT can be formed of a semiconductor material such as an oxide semiconductor, amorphous silicon, or polysilicon, but is not limited thereto. Further, other transistors, such as a switching transistor, a sensing transistor, and an emission control transistor, other than the driving transistor DT, can be further disposed. The active layers of the transistors can also be formed of a semiconductor material, such as an oxide semiconductor, amorphous silicon, or polysilicon, but are not limited thereto. The active layer of the transistor included in the pixel circuit, such as the driving transistor DT, the switching transistor, the sensing transistor, and the emission control signal, can be formed of the same material, or formed of different materials.

In the active area AA of the substrate SUB, a first insulating layer IL1 can be disposed on the active layer ACT and the buffer layer BUF. Further, the first insulating layer IL1 can also be disposed on the buffer layer BUF disposed at the outermost periphery of the first non-active area NA1. The first insulating layer IL1 can be an insulating layer which electrically insulates the active layer ACT and the gate electrode GE. The first insulating layer IL1 in the active area AA can extend to a part of the first non-active area NA1. At this time, the first insulating layer IL1 extending to the first non-active area NA1 can be cut off by the third dam DM3.

Further, the first insulating layer IL1 can also be disposed on the buffer layer BUF disposed on the outermost periphery of the display panel 110. Therefore, the first insulating layers IL1 can be spaced apart from each other in a part of the first non-active area NA1. The first insulating layer IL1 extending from the active area AA and the first insulating layer IL1 which is spaced apart from the first non-active area NA1 to be disposed on the outermost periphery of the display panel 110 can be formed of the same material. Further, the first insulating layers can be formed by the same process.

A partial side surface of the first insulating layer IL1 disposed at the outermost periphery of the display panel 110 in the first non-active area NA1 can be exposed to the outside of the display panel 110 through the side surface of the display panel 110. The first insulating layer IL1 can be configured by a single layer or a double layer of silicon oxide (SiOx) or silicon nitride (SiNx), but is not limited thereto.

In the active area AA of the substrate SUB, a gate electrode GE can be disposed on the first insulating layer IL1. The gate electrode GE can be configured by a conductive material, such as copper (Cu), aluminum (Al), molybdenum (Mo), nickel (Ni), titanium (Ti), chrome (Cr), or an alloy thereof, but is not limited thereto.

At least one crack sensing pattern PCD can be disposed on the first insulating layer IL1 which extends from the active area AA in the first non-active area NA1 of the substrate SUB. At least one crack sensing pattern PCD can be disposed between the plurality of dams. For example, at least one crack sensing pattern PCD can be disposed to be more adjacent to the active area AA, than the third dam DM3 disposed at the outermost periphery, among a plurality of dams disposed in the first non-active area NA1 of the substrate SUB. At least one crack sensing pattern PCD can be spaced apart from the inside to the outside of the display panel 110. Further, at least one crack sensing pattern PCD can be disposed so as to enclose the active area AA. Therefore, at least one crack sensing pattern PCD can detect a crack generated in the first non-active area NA1 of the display panel 110.

In the first non-active area NA1 of the substrate SUB, at least one metal layer ML is disposed on the first insulating layer IL1 disposed at the outermost periphery. At least one metal layer ML is disposed on at least one side portion in the first non-active area NA1 of the substrate SUB. At least one side surface of at least one metal layer ML is exposed to the outside through one side surface of the display panel 110. Therefore, at least one metal layer ML can be visible from one side surface direction of the display panel 110. At least one metal layer ML can be used as an alignment mark together with a groove H disposed on a side surface of the support member 130 to be described below.

At least one metal layer ML can be disposed on at least two side portions of the substrate SUB. For example, a part of at least one metal layer ML can be disposed on one side portion of the substrate SUB and the other part of at least one metal layer ML can be disposed on the other side portion which is opposite to the one side portion of the substrate SUB. Alternatively, a part of at least one metal layer ML can be disposed on one side portion of the substrate SUB and the other part of at least one metal layer ML can be disposed on the other side portion which is perpendicular to the one side portion of the substrate SUB. Alternatively, a part of at least one metal layer ML can be disposed on one side portion of the substrate SUB, the other part of at least one metal layer ML can be disposed on the other side portion which is opposite to the one side portion of the substrate SUB, and still another part of at least one metal layer ML can be disposed on the other side portion perpendicular to the one side portion of the substrate SUB. Therefore, as illustrated in FIGS. 1 and 2, the display panel 110 of the display device 100 according to the embodiment of the present disclosure includes at least one metal layer ML exposed to at least one side surface.

For the convenience of description, even though in FIG. 4, the side surface of at least one metal layer ML has a rectangular shape, it is not limited thereto. For example, a shape of at least one side surface of at least one metal layer ML which is exposed to the outside can have various shapes, such as a triangle, a circle, or an oval.

At least one metal layer ML can be disposed to be spaced apart from at least one crack sensing pattern PCD. For example, at least one metal layer ML and at least one crack sensing pattern PCD can be respectively disposed on first insulating layers IL1 which are spaced apart from each other. The crack sensing pattern PCD can be disposed in the inside of the display panel 110, more than the third dam DM3 disposed at the outermost periphery, among the plurality of dams, and at least one metal layer ML can be disposed at the outside of the display panel 110 more than the third dam DM3.

At least one metal layer ML can be disposed on the same layer as at least one crack sensing pattern PCD. At least one metal layer ML can be formed of the same material as at least one crack sensing pattern PCD. Therefore, at least one metal layer ML can be formed by the same process as at least one crack sensing pattern PCD.

At least one metal layer ML can be disposed on the same layer as a gate electrode of any one of the plurality of transistors disposed in the active area AA. Further, at least one metal layer ML can be formed of the same material as a gate electrode of any one of the plurality of transistors disposed in the active area AA. For example, at least one metal layer ML can be disposed on the same layer as a gate electrode GE of a driving transistor DT disposed in the active area AA. Further, at least one metal layer ML can be formed of the same material as a gate electrode GE of the driving transistor DT disposed in the active area AA.

In the active area AA of the substrate SUB, a second insulating layer IL2 can be disposed on the gate electrode GE. In the second insulating layer IL2, a contact hole through which the source electrode SE and the drain electrode DE are each connected to the active layer ACT can be formed. The second insulating layer IL2 is an insulating layer which protects configurations therebelow and can be configured by a single layer or a double layer of silicon oxide (SiOx) or silicon nitride (SiNx), but is not limited thereto.

The second insulating layer IL2 can be disposed to be extended from the active area AA to a part of the first non-active area NA1. At this time, the second insulating layer IL2 which extends to a part of the first non-active area NA1 can be cut off by the third dam DM3.

Further, the second insulating layer IL2 can also be disposed on at least one metal layer ML disposed at the outermost periphery of the first non-active area NA1. Here, the second insulating layer IL2 can be disposed so as to enclose the remaining side surfaces of at least one metal layer ML excluding one side surface which is exposed to the outside and can be disposed so as to cover a top surface of at least one metal layer ML. Therefore, the remaining side surfaces of at least one metal layer ML excluding one side surface which is exposed to the outside can be enclosed by the first insulating layer IL1 and the second insulating layer IL2.

The second insulating layer IL2 which covers at least one metal layer ML and the second insulating layer IL2 which extends from the active area AA can be formed of the same material and can be disposed by the same process. However, the second insulating layer IL2 which covers at least one metal layer ML and the second insulating layer IL2 which extends from the active area AA can be spaced apart from each other by the third dam DM3. Therefore, the second insulating layer IL2 may not be disposed in a partial area of the first non-active area NA1.

In the active area AA, a first conductive layer TM can be disposed on the second insulating layer IL2. The first conductive layer TM can be disposed on the gate electrode GE. The first conductive layer TM can configure the storage capacitor together with the gate electrode GE. However, the first conductive layer TM can be omitted depending on the embodiment.

In the first non-active area NA1, at least one crack suppression pattern PCS can be disposed on the second insulating layer IL2. At least one crack suppression pattern PCS can be disposed between a plurality of dams disposed in the first non-active area NA1. At least one crack suppression pattern PCS can be disposed inside the display panel 110 more than the third dam DM3 which is disposed at the outermost periphery, among the plurality of dams. For example, at least one crack suppression pattern PCS can be disposed between the second dam DM2 and the third dam DM3, but is not limited thereto.

At least one crack suppression pattern PCS can be disposed on at least one crack sensing pattern PCD. At least one crack suppression pattern PCS can be disposed to enclose the active area AA in the first non-active area NA1. Therefore, at least one crack suppression pattern PCS can suppress a crack generated in the first non-active area NA1 of the display panel 110 from propagating to the active area AA.

At least one crack suppression pattern PCS can be disposed on the same layer as the first conductive layer TM. At least one crack suppression pattern PCS can be formed of the same material as the first conductive layer TM, but is not limited thereto.

In the active area AA of the substrate SUB, a third insulating layer IL3 can be disposed on the first conductive layer TM. At this time, the third insulating layer IL3 disposed in the active area AA can extend to a part of the first non-active area NA1. Therefore, the third insulating layer IL3 can cover both the first conductive layer TM disposed in the active area AA and the crack suppression pattern PCS disposed in the first non-active area NA1. One end of the third insulating layer IL3 can be disposed between the plurality of dams disposed in the first non-active area NA1. For example, the third insulating layer IL3 extending from the active area AA can be cut off by the third dam DM3. Therefore, the third insulating layer IL3 may not be disposed in a part of the first non-active area NA1. The third insulating layer IL3 can also be disposed on the second insulating layer IL2 disposed at the outermost periphery of the first non-active area NA1. At this time, one side surface of the third insulating layer IL3 is disposed at the outermost periphery of the display panel 110 to be exposed to the outside through the side surface of the display panel 110.

In the active area AA of the substrate SUB, the source electrode SE and the drain electrode DE of the driving transistor DT can be disposed on the third insulating layer IL3. The source electrode SE and the drain electrode DE of the driving transistor DT can be connected to the active layer ACT of the driving transistor DT through a contact hole formed in the first insulating layer IL1, the second insulating layer IL2, and the third insulating layer IL3. Therefore, the source electrode SE of the driving transistor DT can be connected to the source region of the active layer ACT through the contact holes formed in the first insulating layer IL1, the second insulating layer IL2, and the third insulating layer IL3. Further, the drain electrode DE of the driving transistor DT can be connected to the drain region of the active layer ACT through the contact holes formed in the first insulating layer IL1, the second insulating layer IL2, and the third insulating layer IL3.

The source electrode SE and the drain electrode DE can be one of molybdenum (Mo), copper (Cu), titanium (Ti), aluminum (Al), chrome (Cr), gold (Au), nickel (Ni), and neodymium (Nd) or an alloy thereof and can be formed by a single layer or a multi-layer, but is not limited thereto.

A second conductive layer SD1 can be disposed on the third insulating layer IL3 in the first non-active area NA1 of the substrate SUB. The second conductive layer SD1 can be disposed on the same layer as the source electrode SE and the drain electrode DE of the driving transistor DT and can be formed of the same material as the source electrode SE and the drain electrode DE, but is not limited thereto. For example, the second conductive layer SD1 can be formed of the same material as the gate electrode GE or the connection electrode CE. The second conductive layer SD1 can serve as a wiring line for supplying a low potential voltage. The second conductive layer SD1 can be disposed so as to at least partially overlap the first dam DM1 and the second dam DM2, but can be disposed so as not to be placed beyond the second dam DM2.

A passivation layer PAS can be disposed on the source electrode SE and the drain electrode DE of the driving transistor DT and the second conductive layer SD1. The passivation layer PAS can be disposed so as to cover at least a part of the driving transistor DT and the second conductive layer SD1. In the active area AA, the passivation layer PAS can include a contact hole to expose the drain electrode DE of the driving transistor DT. Further, in the first non-active area NA1, the passivation layer PAS can include a contact hole to expose the second conductive layer SD1. The passivation layer PAS can be configured by a single layer of silicon nitride (SiNx) or silicon oxide (SiOx) or a multi-layer thereof, but is not limited thereto.

In the active area AA and a part of the first non-active area NA1 of the substrate SUB, a first planarization layer PNL1 can be disposed on the passivation layer PAS. The first planarization layer PNL1 may not be disposed in an area in which at least one of the second conductive layer SD1 and the plurality of dams is disposed in the non-active area NA1. For example, the first planarization layer PNL1 may not be disposed in an area in which the plurality of dams is disposed and an area of the second conductive layer SD1 which is exposed by the passivation layer PAS.

A contact hole which exposes the drain electrode DE can be formed in the first planarization layer PNL1. The first planarization layer PNL1 can be a layer which protects the driving transistor DT and makes a step on the substrate SUB gentle to planarize an upper portion of the substrate SUB. For example, the first planarization layer PNL1 can be formed of an organic material such as acryl resin, epoxy resin, phenolic resin, polyamide resin, or polyimide resin, but is not limited thereto.

In the active area AA of the substrate SUB, a connection electrode CE can be disposed on the first planarization layer PNL1. The connection electrode CE can be connected to the drain electrode DE of the driving transistor DT through the contact holes of the first planarization layer PNL1 and the passivation layer PAS which expose the drain electrode DE. The connection electrode CE can serve to electrically connect the driving transistor DT and the display element LED. For example, the connection electrode CE can serve to electrically connect the drain electrode DE of the driving transistor DT and a first electrode AND of the display element LED. The connection electrode CE can be formed of a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof, but is not limited thereto. The connection electrode CE can be formed of the same material as the source electrode SE and the drain electrode DE of the driving transistor DT.

In the first non-active area NA1 of the substrate SUB, a third conductive layer SD2 can be disposed on the first planarization layer PNL1. The third conductive layer SD2 can be in contact with a top surface of the second conductive layer SD1, in an area in which the first planarization layer PNL1 and the passivation layer PAS are open. The third conductive layer SD2 is disposed between the second conductive layer SD1 and the plurality of dams so that one end of the third conductive layer SD2 can be disposed above the first planarization layer PNL1 and the other end of the third conductive layer SD2 can be disposed above the passivation layer PAS.

Further, the second conductive layer SD1 can serve as a wiring line for supplying a low potential voltage so that the third conductive layer SD2 can serve to supply the low potential voltage to the second electrode CAT of the display element LED. The third conductive layer SD2 can be formed on the same layer as the connection electrode CE and can be formed of the same material as the connection electrode CE, but is not limited thereto. The third conductive layer SD2 can be formed of a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof, but is not limited thereto.

In the active area AA and a part of the first non-active area NA1 of the substrate SUB, a second planarization layer PNL2 can be disposed on the connection electrode CE and the first planarization layer PNL1. For example, the second planarization layer PNL2 can be disposed so as to cover the connection electrode CE on the first planarization layer PNL1. A contact hole which exposes the connection electrode CE can be formed in the second planarization layer PNL2. The second planarization layer PNL2 can be an organic material layer which further makes the step of a lower structure due to the connection electrode CE on the first planarization layer PNL1 gentle to additionally protect the lower structure. For example, the second planarization layer PNL2 can be formed of an organic material, such as acryl resin, epoxy resin, phenolic resin, polyamide resin, and polyimide resin, but is not limited thereto. The second planarization layer PNL2 can be formed of the same material as the first planarization layer PNL1.

In a part of the first non-active area NA1 of the substrate SUB, the second planarization layer PNL2 can be disposed on the first planarization layer PNL1. The second planarization layer PNL2 can be disposed so as to cover one side of the third conductive layer SD2.

In the active area AA of the substrate SUB, the display element LED can be disposed on the second planarization layer PNL2. The display element LED can include a first electrode AND, an emission structure EL, and a second electrode CAT. In the active area AA of the substrate SUB, the first electrode AND of the display element LED can be disposed on the second planarization layer PNL2. The first electrode AND can be electrically connected to the connection electrode CE through the contact hole formed in the second planarization layer PNL2. Therefore, the first electrode AND can be electrically connected to the connection electrode CE through the contact hole formed in the second planarization layer PNL2 to be electrically connected to the driving transistor DT.

The first electrode AND can be formed to have a multi-layered structure including a transparent conductive film and an opaque conductive film having high reflection efficiency. The transparent conductive film can be formed of a material having a relatively high work function such as indium tin oxide (ITO) or indium zinc oxide (IZO). The opaque conductive film can be formed to have a single-layered or a double-layered structure including aluminum (Al), silver (Ag), copper (Cu), lead (Pb), molybdenum (Mo), and titanium (Ti), or an alloy thereof. For example, the first electrode AND can be formed to have a structure in which a transparent conductive film, an opaque conductive film, and a transparent conductive film can be sequentially laminated. However, the first electrode AND is not limited thereto, but can also be formed to have a structure in which the transparent conductive film and the opaque conductive film are sequentially laminated. The first electrode AND can be an anode electrode, but is not limited thereto.

Further, the emission structure EL including an emission layer can be further disposed on the first electrode AND. The emission structure EL can be formed by laminating a hole layer, an emission layer, and an electron layer on the first electrode AND in this order or a reverse order. Furthermore, the emission structure EL can include first and second emission structures which are opposite to each other with a charge generating layer therebetween. In this case, any one emission layer of the first and second emission structures generates blue light and the other one emission layer of the first and second emission structures generates yellow-green light so that white light can be generated by the first and the second emission structures. The white light generated in the emission structure EL is incident onto a color filter disposed above the emission structure EL to implement color images.

In addition, individual emission structures EL generate color light corresponding to individual sub pixels without having separate color filters to implement color images. For example, the emission structure EL of a red sub pixel can generate red light, the emission structure EL of a green sub pixel can generate green light, and the emission structure EL of a blue sub pixel can generate blue light.

A bank BNK can be disposed on the first electrode AND and the second planarization layer PNL2. The bank BNK can also be disposed in the active area AA and a part of the first non-active area NA1. In the active area AA of the substrate SUB, an opening which exposes the first electrode AND can be formed in the bank BNK. The bank BNK can be disposed so as to cover both ends of the first electrode AND. A spacer SPC can be further disposed on the bank BNK.

The bank BNK and the spacer SPC can be formed of the same material. Further, the bank BNK and the spacer SPC can be formed of an organic material. For example, the bank BNK and the spacer SPC can be formed of polyimide, acryl, or benzocyclobutene (BCB) resin, but the present disclosure is not limited thereto.

In the active area AA of the substrate SUB, a second electrode CAT can be further disposed on emission structure EL. The second electrode CAT can be disposed on a part of the bank BNK and a part of the spacer SPC. Further, the second electrode CAT can extend to the first non-active area NA1. The second electrode CAT can be electrically connected to the third conductive layer SD2 in the first non-active area NA1. Therefore, the second electrode CAT can be electrically connected to the second conductive layer SD1 through the third conductive layer SD2. The second electrode CAT can be disposed on the emission structure EL so as to be opposite to the first electrode AND with the emission structure EL therebetween. The second electrode CAT can be a cathode electrode, but is not limited thereto.

An encapsulation unit ENCAP which covers the second electrode CAT can be disposed on the second electrode CAT. The encapsulation unit ENCAP is formed to cover the display element LED to suppress the permeation of the moisture to the display element LED.

The encapsulating unit ENCAP can include at least one inorganic encapsulation layer and at least one organic encapsulation layer. For example, the encapsulation unit ENCAP can include a first inorganic encapsulation layer EPAS1, an organic encapsulation layer PCL, and a second inorganic encapsulation layer EPAS2. The first inorganic encapsulation layer EPAS1 of the encapsulation unit ENCAP can be disposed on the second electrode CAT. The organic encapsulation layer PCL can be disposed on the first inorganic encapsulation layer EPAS1.

Further, the second inorganic encapsulation layer EPAS2 can be disposed on the organic encapsulation layer PCL. The first inorganic encapsulation layer EPAS1 and the second inorganic encapsulation layer EPAS2 of the encapsulation unit ENCAP can be formed of an inorganic material, such as silicon nitride (SiNx) or silicon oxide (SiOx). The organic encapsulation layer PCL of the encapsulation unit ENCAP can be formed of an organic material, such as acryl resin, epoxy resin, phenolic resin, polyamide resin, or polyimide resin, but is not limited thereto.

The first inorganic encapsulation layer EPAS1 and the second inorganic encapsulation layer EPAS2 of the encapsulation unit ENCAP can be in contact with each other in the first non-active area NA1. For example, the first inorganic encapsulation layer EPAS1 and the second inorganic encapsulation layer EPAS2 of the encapsulation unit ENCAP can be in contact with each other between the second dam DM2 and the third dam DM3. Therefore, the second dam DM2 and the third dam DM3 can be disposed to be covered by the first inorganic encapsulation layer EPAS1 and the second inorganic encapsulation layer EPAS2.

A plurality of dams can be disposed in the first non-active area NA1 of the substrate SUB. The plurality of dams can suppress the overflow of the organic encapsulation layer PCL of the encapsulation unit ENCAP. The plurality of dams can include a first dam DM1 which is the most adjacent to the active area AA, a third dam DM3 which is furthest outside from the active area AA, and a second dam DM2 between the first dam DM1 and the third dam DM3.

The first dam DM1 can be disposed so as to enclose an outer periphery of the active area AA. The first dam DM1 can be disposed on the third conductive layer SD2 in the first non-active area NA1.

The second dam DM2 can be disposed at the outside of the display panel 110 more than the first dam DM1 and can be disposed to enclose the first dam DM1. The second dam DM2 can overlap parts of the second conductive layer SD1, the passivation layer PAS, and the third conductive layer SD2. Further, the second dam DM2 can be disposed to cover ends of the third conductive layer SD2 and the passivation layer PAS.

The third dam DM3 can be disposed at the outside of the display panel 110 more than the second dam DM2 and can be disposed at the outermost side of the plurality of dams. Therefore, the third dam DM3 can be disposed to cover all ends of the buffer layer BUF, the first insulating layer IL1, the second insulating layer IL2, and the third insulating layer IL3. The third dam DM3 can be disposed to be spaced apart towards the inside of the display panel 110, more than at least one metal layer ML. The third dam DM3 can be spaced apart from the buffer layer BUF, the first insulating layer IL1, the second insulating layer IL2, and the third insulating layer IL3 disposed above and below at least one metal layer ML.

Each of the plurality of dams can be formed as a multi-layer. For example, the first dam DM1 can include a first layer DM1-1 of the first dam DM1, a second layer DM1-2 of the first dam DM1, and a third layer DM1-3 of the first dam DM1. The second dam DM2 can include a first layer DM2-1 of the second dam DM2, a second layer DM2-2 of the second dam DM2, and a third layer DM2-3 of the second dam DM2. Further, the third dam DM3 can include a first layer DM3-1 of the third dam DM3 and a second layer DM3-2 of the third dam DM3.

The first layer DM1-1 of the first dam DM1, the first layer DM2-1 of the second dam DM2, and the first layer DM3-1 of the third dam DM3 can be formed by the same process and the same material as the second planarization layer PNL2, but are not limited thereto.

The second layer DM1-2 of the first dam DM1 can be disposed on the first layer DM1-1 of the first dam DM1 and the second layer DM2-2 of the second dam DM2 can be disposed on the first layer DM2-1 of the second dam DM2. Further, the second layer DM3-2 of the third dam DM3 can be disposed on the first layer DM3-1 of the third dam DM3. At this time, the second layer DM1-2 of the first dam DM1, the second layer DM2-2 of the second dam DM2, and the second layer DM3-2 of the third dam DM3 can be disposed to cover the first layer DM1-1 of the first dam DM1, the first layer DM2-1 of the second dam DM2, and the first layer DM3-1 of the third dam DM3, respectively. The second layer DM1-2 of the first dam DM1, the second layer DM2-2 of the second dam DM2, and the second layer DM3-2 of the third dam DM3 can be formed by the same process and the same material as the bank BNK, but are not limited thereto.

The third layer DM1-3 of the first dam DM1 can be disposed on the second layer DM1-2 of the first dam DM1. The third layer DM2-3 of the second dam DM2 can be disposed on the second layer DM2-2 of the second dam DM2. At this time, the third layer DM1-3 of the first dam DM1 and the third layer DM2-3 of the second dam DM2 can be formed by the same process and the same material as the spacer SPC, but are not limited thereto.

In the embodiment of the present disclosure, it is illustrated that the display device 100 includes a plurality of dams including three dams DM1, DM2, and DM3 formed of a double layer or a triple layer, but is not limited thereto. For example, each of the plurality of dams can be formed as a single layer or formed of four or more layers. Further, one dam can enclose the active area AA.

A protection layer SPAC can be disposed on the encapsulation unit ENCAP in the active area AA and the first non-active area NA1. The protection layer SPAC can protect configurations disposed therebelow in the active area AA and the first non-active area NA1. The protection layer SPAC can be disposed to cover all from the active area AA to the third dam DM3 which is disposed at the outermost side of the plurality of dams. However, the protection layer SPAC may not be disposed on the buffer layer BUF disposed at the outermost periphery of the display panel 110, the first insulating layer IL1, the plurality of metal layers ML, the second insulating layer IL2, and the third insulating layer IL3. Therefore, an end of the protection layer SPAC can be in contact with the substrate SUB in which the buffer layer BUF, the first insulating layer IL1, the plurality of metal layers ML, the second insulating layer IL2, and the third insulating layer IL3 are not disposed in the first non-active area NA1. For example, the protection layer SPAC can be formed of an organic material such as acryl resin, epoxy resin, phenolic resin, polyamide resin, or polyimide resin, but is not limited thereto.

A support member 130 is disposed below the display panel 110. The support member 130 can be disposed below the active area AA and the first non-active area NA1 of the substrate SUB of the display panel 110. Further, an area of the support member 130 can have the same area ratio as the entire area of the active area AA and the first non-active area NA1 of the substrate SUB.

At least one groove H is included on a side surface of the support member 130. At this time, at least one metal layer ML exposed through the side surface of the display panel 110 and at least one groove H disposed on the side surface of the support member 130 can be disposed so as to correspond to each other. At this time, a shape of the at least one groove H disposed on the side surface of the support member 130 is not specifically limited and can be the same as or different from the shape of at least one metal layer ML exposed on the side surface of the display panel 110. However, the at least one groove H disposed on the side surface of the support member 130 and at least one metal layer ML exposed on the side surface of the display panel 110 can be alignment marks for aligning the support member 130 and the display panel 110. Therefore, a center line CL of the at least one groove H disposed on the side surface of the support member 130 and a center line CL of at least one metal layer ML exposed on the side surface of the display panel 110 can correspond to each other to match.

As the development of a flexible display device progresses, a flexible substrate having flexibility, such as plastic which is a flexible material, is increasingly used to implement a flexible display device. However, there can be an issue in that the flexible substrate having flexibility can be vulnerable to external impacts or permeation of moisture. Accordingly, a metal plate for suppressing the impact from the outside or permeation of moisture or oxygen can be disposed below the flexible substrate. At this time, an alignment mark is formed below the display panel for an alignment process of placing a metal plate on a desired position below the display panel which uses the flexible substrate. However, the metal plate to be disposed below the display panel is opaque so that a hole is formed in a partial outer periphery of the metal plate to identify an alignment mark disposed below the display panel. Thereafter, the alignment mark formed below the display panel and the hole formed in a partial outer periphery of the metal plate are aligned to align and bond the display panel and the metal plate.

However, the alignment process as described above can cause a limitation in that a part of the metal plate may need to be damaged to identify the alignment mark, due to the opacity of the metal plate. Therefore, there can be an issue in that the entire area of the support substrate of the display panel is not completely supported or protected by the metal plate.

Therefore, the display device 100 according to the embodiment of the present disclosure includes a plurality of metal layers ML which is exposed to the side surface of the display panel 110. Further, an identifiable groove H is formed on the side surface of the support member 130 disposed below the display panel 110. By doing this, even though the entire lower area of the display panel 110 is blocked by the support member 130, the alignment process can be easily performed through the display panel 110 and the side surface of the support member 130.

Further, in the display device 100 according to the embodiment of the present disclosure, the alignment mark is not identified through the display panel 110 and the lower portion of the support member 130 so that the support member 130 with an opaque material can be disposed below the display panel 110 to entirely support. For example, on the plane, the entire bottom surface of the display panel 110 can be supported by the support member 130. Therefore, in the display device 100 according to the embodiment of the present disclosure, the entire display panel 110 can be protected from the external impact or the permeation of the moisture or oxygen.

Further, in the display device 100 according to the embodiment of the present disclosure, a narrow bezel can be implemented. As described above, the support member 130 can support the entire display panel 110 so that a protection area of the display panel 110 by the support member 130 can be increased. Therefore, the active area AA which is stably driven in the display panel 110 can expand and sizes of the non-active areas NA1 and NA2 can be reduced.

Further, in the display device 100 according to the embodiment of the present disclosure, an additional process for forming the metal layer ML is not necessary. For example, the plurality of metal layers ML can be simultaneously formed with the same material as the gate electrode GE and the crack sensing pattern PCD in the display panel 110. Accordingly, in the display device 100 according to the embodiment of the present disclosure, the existing process can be used as it is without an additional process for forming a separate alignment mark so that the cost for the alignment process may not be added and the additional process may not be necessary.

The embodiments of the present disclosure can also be described as follows:

According to an aspect of the present disclosure, there is provided a display device. The display device comprises a substrate including an active area and a first non-active area which encloses the active area, at least one metal layer which is disposed on at least one side portion of the substrate and includes one surface exposed to an outside, and a support member which is disposed on a bottom surface of the substrate and includes at least one groove on at least one side surface of the support member, wherein the at least one metal layer and the at least one groove disposed on the side surface of the support member are disposed so as to correspond to each other.

At least one metal layer and at least one groove can be alignment marks.

At least one metal layer can be disposed on at least two side portions of the substrate.

At least one metal layer can be disposed on one side portion of the substrate and the other side portion vertically adjacent to the one side portion.

The display device can further include at least one crack sensing pattern and at least one dam disposed in the first non-active area on the substrate, wherein the at least one metal layer is formed of the same material as the at least one crack sensing pattern.

An outermost dam of the at least one dam can be disposed to be spaced more inward than the at least one metal layer.

At least one metal layer and the at least one crack sensing pattern can be disposed on the same layer.

The substrate can further include a bending area which can extend from one side of the first non-active area to be bent, and a second non-active area which can extend from the bending area to be disposed below the active area, and the support member can be disposed below the active area and the first non-active area of the substrate.

The remaining surfaces of the at least one metal layer excluding the one surface exposed to the outside can be enclosed by a plurality of inorganic insulating layers.

The display device can further include a plurality of transistors disposed in the active area, wherein the at least one metal layer can be formed of the same material as a gate electrode of the plurality of transistors.

An inorganic insulating layer disposed between the at least one metal layer and the substrate and an inorganic insulating layer disposed between the gate electrode of the plurality of transistors and the substrate can be formed of the same material.

The inorganic insulating layer disposed between the at least one metal layer and the substrate and the inorganic insulating layer disposed between the gate electrode of the plurality of transistors and the substrate can be spaced apart from each other.

The display device can further comprise a planarization layer disposed on the plurality of transistors, wherein an inorganic insulating layer disposed on the at least one metal layer and an inorganic insulating layer disposed between the gate electrode of the plurality of transistors and the planarization layer can be formed of the same material.

Although the embodiments of the present disclosure have been described in detail with reference to the accompanying drawings, the present disclosure is not limited thereto and can be embodied in many different forms without departing from the technical concept of the present disclosure. Therefore, the embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a substrate including an active area and a first non-active area disposed adjacent to the active area;
at least one metal layer disposed on at least one side portion of the substrate and including one surface exposed to an outside; and
a support member disposed on a bottom surface of the substrate and including at least one groove disposed on a side surface of the support member,
wherein the at least one metal layer and the at least one groove disposed on the side surface of the support member are disposed to correspond to each other.

2. The display device according to claim 1, wherein the at least one metal layer and the at least one groove are alignment marks.

3. The display device according to claim 1, wherein the at least one metal layer is disposed on at least two side portions of the substrate.

4. The display device according to claim 3, wherein the at least one metal layer is disposed on one side portion and another side portion of the substrate, the another side portion being vertically adjacent to the one side portion of the substrate.

5. The display device according to claim 1, further comprising:
at least one crack sensing pattern and at least one dam disposed in the first non-active area on the substrate,
wherein the at least one metal layer is formed of a same material as the at least one crack sensing pattern.

6. The display device according to claim 5, wherein an outermost dam of the at least one dam is located more inwardly than the at least one metal layer.

7. The display device according to claim 5, wherein the at least one metal layer and the at least one crack sensing pattern are disposed on a same layer.

8. The display device according to claim 1, wherein the substrate further includes:
a bending area extending from one side of the first non-active area and configured to be bendable, and
a second non-active area extending from the bending area and disposed below the active area, and
wherein the support member is disposed below the active area and the first non-active area of the substrate.

9. The display device according to claim 1, wherein remaining surfaces of the at least one metal layer excluding the one surface exposed to the outside are enclosed by a plurality of inorganic insulating layers.

10. The display device according to claim 1, further comprising:
a plurality of transistors disposed in the active area,
wherein the at least one metal layer is formed of a same material as a gate electrode of the plurality of transistors.

11. The display device according to claim 10, wherein an inorganic insulating layer disposed between the at least one metal layer and the substrate and an inorganic insulating layer disposed between the gate electrode of the plurality of transistors and the substrate are formed of a same material.

12. The display device according to claim 11, wherein the inorganic insulating layer disposed between the at least one metal layer and the substrate and the inorganic insulating layer disposed between the gate electrode of the plurality of transistors and the substrate are spaced apart from each other.

13. The display device according to claim 10, further comprising:
a planarization layer disposed on the plurality of transistors,
wherein an inorganic insulating layer disposed on the at least one metal layer and an inorganic insulating layer disposed between the gate electrode of the plurality of transistors and the planarization layer are formed of a same material.
